(19) United States
(12) Patent Application Publication
(10) Pub. No.: US 2025/0194132 A1
(43) Pub. Date: Jun. 12, 2025

(54) SEMICONDUCTOR DEVICE HAVING SPLIT GATES AND METHOD FOR MANUFACTURING THE SAME

(71) Applicant: TAIWAN SEMICONDUCTOR MANUFACTURING COMPANY LTD., HSINCHU (TW)

(72) Inventors: YUN-CHI WU, TAINAN CITY (TW); CHENG-BO SHU, TAINAN CITY (TW); SHIH-JUNG TU, TAINAN CITY (TW); SHIANG-HUNG HUANG, NEW TAIPEI CITY (TW); HSIN FU LIN, HSINCHU COUNTY (TW); PO-WEI LIU, TAINAN CITY (TW); CHIA-TA HSIEH, TAINAN (TW); PEI-SHAN HSIEH, HSINCHU COUNTY (TW)

(21) Appl. No.: 18/531,753

(22) Filed: Dec. 7, 2023

(51) Int. Cl. H01L 29/66; H01L 29/06; H01L 29/08; H01L 29/10; H01L 29/78

(52) U.S. Cl. CPC H10D 30/024; H10D 30/0221; H10D 30/0285; H10D 30/603; H10D 62/116; H10D 62/153; H10D 62/157; H10D 62/393

(57) ABSTRACT

A method for manufacturing a semiconductor device is provided. A gate oxide layer is formed over a high-voltage N-type well region, an N-type well region and a P-type well region. The gate oxide layer includes a first layer portion and a second layer portion. The first and second layer portions have different thicknesses. A main gate is formed on the first layer portion and the second layer portion. At least one split gate is formed on the second layer portion, and the main gate and the split gate extend along an interface between the high-voltage N-type well region and the P-type well region. An inter-level dielectric (ILD) layer is formed over the main gate and the split gate. A plurality of connecting features penetrating the ILD layer to contact the main gate and the split gate are formed. An electrode is formed to contact the connecting features.

### BACKGROUND

Bipolar/CMOS/DMOS (BCD) devices include a bipolar region to perform analog functions, a complementary metal oxide semiconductor (CMOS) region to perform digital functions and a double diffused metal oxide semiconductor (DMOS) region including power and high-voltage devices. BCD devices are used in communications applications such as phones and tablets as well as automotive applications, e.g. for mirror positioning, seat adjustment and others. By integrating three distinct types of components on a single die, BCD technology can reduce the number of components in the bill of materials (BOM). Fewer chip components in the BoM conserves board footprint, and thus reduces costs.

Providing ease of integration and compatibility of control circuitry, laterally diffused metal-oxide-semiconductors (LDMOS) are widely used in power devices for BCD technology, with power consumption of major concern in LDMOS devices. A power LDMOS delivering higher breakdown voltage (BV) while minimizing specific on-resistance (Rds (on)) is called for to reduce conduction loss. An ultra-low Rds (on) is desirable for quick-charging devices to achieve high current capacity.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart of a method for manufacturing a semiconductor device having split gates, in accordance with some embodiments of the disclosure.

FIGS. 2 to 11 are schematic views of intermediate stages of the method depicted in FIG. 1.

FIG. 12 is a top view of a semiconductor device, in accordance with some embodiments of the disclosure.

FIG. 13 is a cross-section of the semiconductor device of FIG. 11 along line A-A′, in accordance with some embodiments of the present disclosure.

FIG. 14 is a perspective view of interconnection structures of the semiconductor device of FIG. 12, in accordance with some embodiments of the present disclosure.

FIG. 15 is an integrated semiconductor device, in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail as follows. It should be appreciated, however, that the present disclosure provides many applicable inventive concepts that can be embodied in a wide variety of specific contexts. The specific embodiments discussed are merely illustrative and do not limit the scope of the disclosure.

Further, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about”. Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Various structures of semiconductor devices, and specifically Bipolar/CMOS/DMOS (BCD) devices are provided in accordance with various exemplary embodiments. Some variations of some embodiments are discussed. Throughout the various views and illustrative embodiments, like reference numbers are used to designate like elements.

High voltage transistor devices are often constructed as field plates. Field plates are conductive elements placed over a channel region to enhance performance of a high voltage transistor device by manipulating the electric field generated by the gate electrode (e.g., reducing the peak electric field). By manipulating the electric field generated by the gate electrode, high voltage transistor devices can achieve higher breakdown voltages. For example, LDMOS (Laterally Diffused Metal Oxide Semiconductor) transistor devices typically include field plates extending to an adjacent drift region disposed between the channel region and the drain region.

Field plates can be formed in many different ways. One is a high-voltage transistor device with a metal field plate, formed simultaneously with the back-end-of-line (BEOL) metal layer to reduce manufacturing costs. The metal field plate is formed over the drift region of the high-voltage transistor and is biased by voltage of the source region of the high-voltage transistor device. The metal field plate is a capacitively coupled field plate, and the field plate effect makes the high-voltage transistor device has a structure similar to MOS capacitor, which can divide the voltage potential, thereby reducing the peak electric field of the component and increasing the breakdown voltage of the component.

To suppress hot carrier injection (HCl) effect, a metal field plate is used in a conventional BCD. By biasing the metal field plate with a source voltage, an electric field corresponding to the biased metal plate is capable of controlling the drift region of the high-voltage device. However, a drain breakdown characteristic BVdss (i.e., drain to source breakdown voltage) is uncontrollable by the metal field plate since an interlayer dielectric (ILD) control capability is limited (i.e., the ILD oxide non-uniformity), i.e., the breakdown is unstable and BVdss fluctuates greatly in the conventional BCD because the ILD layer is too thick. Furthermore, implant of the drift region needs to be fine-tuned to minimize BVdss/HCl fluctuation of the metal field plate.

According to the embodiments of the present disclosure, semiconductor devices with poly field plate (PFP) and a manufacturing method for the same are provided. In the semiconductor devices, a number of split gates are formed on a reduced surface field oxide (ROX) layer to serve as the PFP for controlling the drift region of the semiconductor device, thereby avoiding uncontrollable BVdss that is caused by the metal field plate with the ILD oxide non-uniformity. Furthermore, the ROX layer has the thicker thickness, thus the split gates and the main gate on the ROX layer can both relieve HCl injection without considering the drift region implant, thereby decreasing fluctuation in HCl and BVdss and decreasing leakage. Moreover, process of the semiconductor device is compatible with regular logic process, thereby decreasing manufacturing costs.

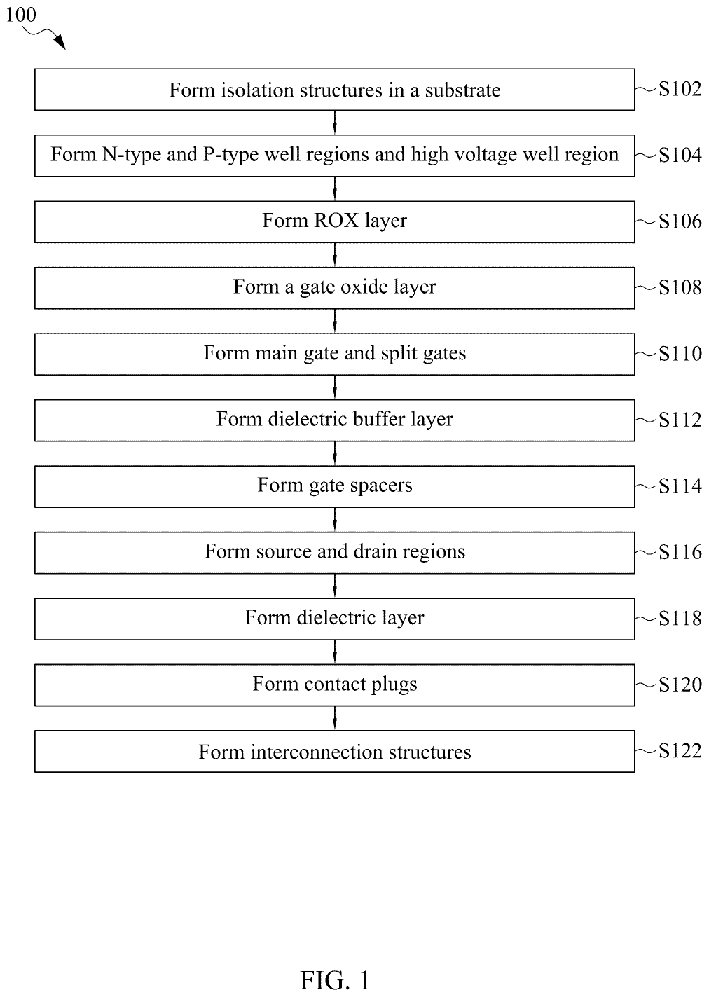

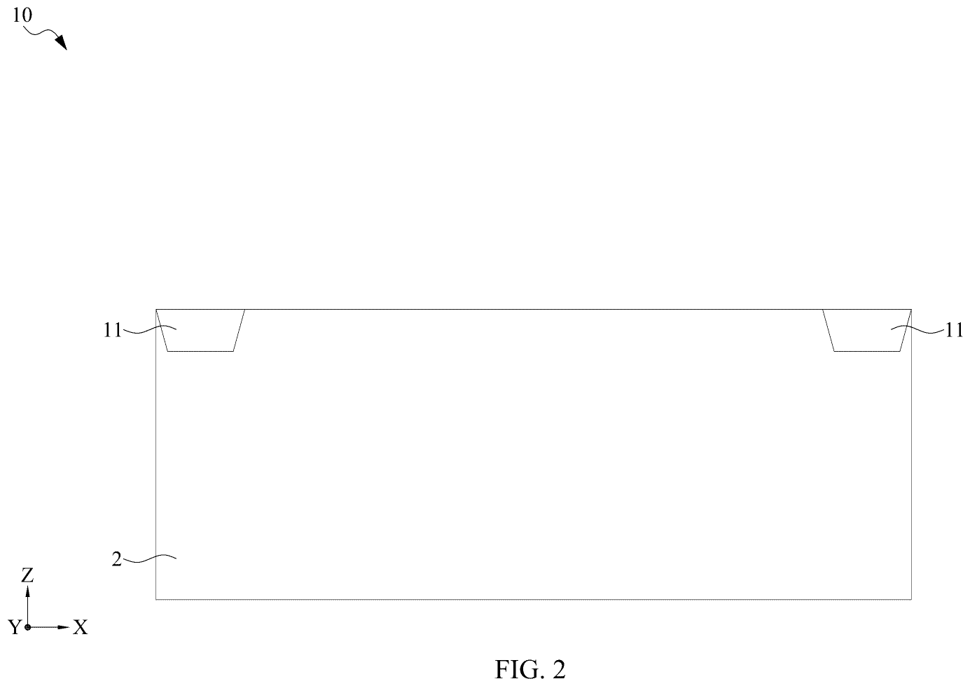

FIG. 1 illustrates a method 100 for manufacturing a semiconductor device having split gates, in accordance with some embodiments of the disclosure. FIGS. 2 to 11 are schematic views of a semiconductor device 10 having split gates during various stages of the method 100 of FIG. 1. The semiconductor device 10 is configured as an N-type LDMOS device in the illustrated embodiments. Other suitable configurations for the semiconductor device 10 are within the contemplated scope of the present disclosure. For example, in some embodiments, the semiconductor device 10 may be configured as a P-type LDMOS device. The method 100 and the semiconductor device 10 are collectively described as follows. However, additional operations can be provided before, after, or during the various stages of the method 100, and some of the operations described herein may be replaced with other operations or be eliminated. Similarly, further additional features may be present in the semiconductor device 10, and/or features present may be replaced or eliminated in additional embodiments.

Referring to FIG. 1, the method 100 starts with operation S102 of forming a number of isolation structures in a substrate. The method 100 continues to operation S104 of forming P-type and N-type well regions and a high-voltage well region in the substrate. The method 100 continues to operation S106 of forming a reduced surface field oxide (ROX) layer on the substrate. The method 100 continues to operation S108 of forming a gate oxide layer. The method 100 continues to operation S110 of forming a main gate and a number of split gates on the gate oxide layer. The method 100 continues to operation S112 of forming a dielectric buffer layer. The method 100 continues to operation S114 of forming gate spacers. The method 100 continues to operation S116 of forming source region and drain region. The method 100 continues to operation S118 of forming an interlayer dielectric (ILD) layer. The method 100 continues to operation S120 of performing a number of contact plugs. The method 100 continues to operation S121 of forming a number of interconnection structures.

While disclosed method 100 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

Corresponding to operation S102 of FIG. 1, FIG. 2 is a cross-sectional view of the semiconductor device 10 including a substrate 2 and a number of isolation structures 11, in accordance with various embodiments.

The substrate 2 may include a semiconductor wafer such as a silicon wafer. Alternatively, the substrate 2 may include other elementary semiconductors such as germanium. The substrate 2 may also include a compound semiconductor such as silicon carbide, gallium arsenic, indium arsenide, and indium phosphide. The substrate 2 may include an alloy semiconductor such as silicon germanium, silicon germanium carbide, gallium arsenic phosphide, and gallium indium phosphide. In one embodiment, the substrate 2 includes an epitaxial layer (epi layer) overlying a bulk semiconductor. Furthermore, the substrate 2 may include a semiconductor-on-insulator (SOI) structure. For example, the substrate 2 may include a buried oxide (BOX) layer formed by a process such as separation by implanted oxygen (SIMOX). In some embodiments, the substrate 2 may include a buried layer such as an n-type buried layer (NBL), a p-type buried layer (PBL), and/or a buried dielectric layer including a buried oxide (BOX) layer.

As described above, the semiconductor device 10 is an N-type LDMOS device, and the substrate 2 includes a P-type silicon substrate (P-substrate). To form complementary transistors, an N-type buried layer, sometimes referred to as a deep N-well (DNW), may be implanted deeply in the P-substrate (e.g., under an active region of the N-type LDMOS device) for forming a P-type LDMOS device in addition to the N-type LDMOS device.

The isolation structures 11 such as a shallow trench isolation (STI) or local oxidation of silicon (LOCOS) may be formed in the substrate 2 to define and electrically isolate various active regions. The semiconductor device 10 is formed in an active region (or oxide diffusion (OD) area) defined by the isolation structures 11.

In some embodiments, the formation of the isolation structure 11 may include dry etching a trench in the substrate 2 and filling the trench with insulator materials such as silicon oxide, silicon nitride, or silicon oxynitride. The filled trench may have a multi-layer structure such as a thermal oxide liner layer filled with silicon nitride or silicon oxide. In some embodiments, the isolation structure 11 may be formed using a processing sequence such as: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical polishing (CMP) processing to etch back and planarize, and using a nitride stripping process to remove the silicon nitride.

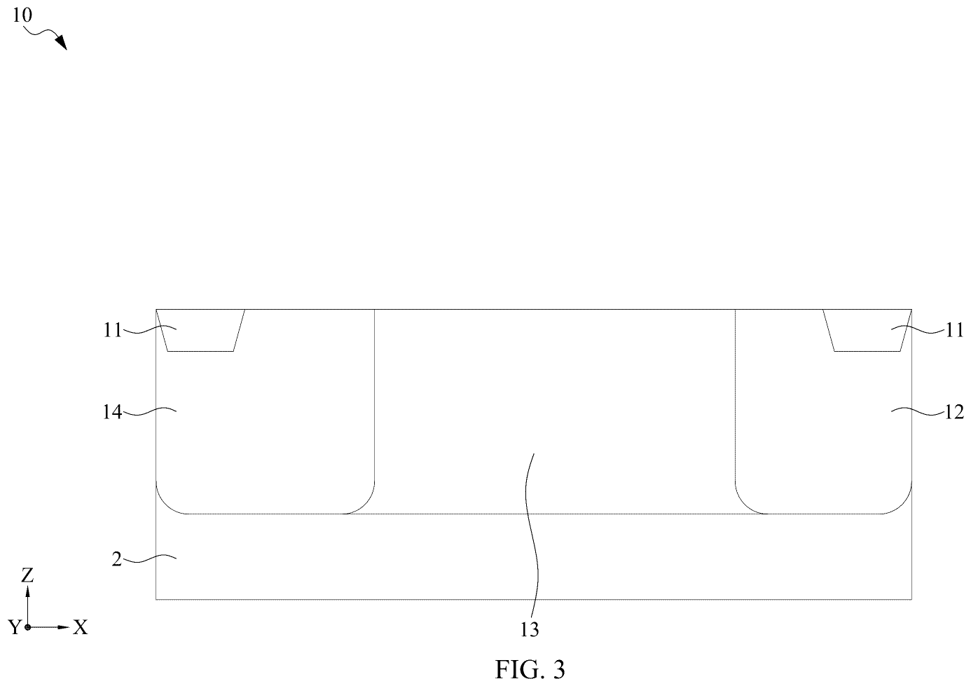

Corresponding to operation S104 of FIG. 1, FIG. 3 is a cross-sectional view of the semiconductor device 10 including an N-type well region 12, a P-type well region 14 and a high-voltage N-type well region 13, in which the isolation structures 11 have been formed. The high-voltage N-type well region 13 may be alternatively referred to as a power N-type well region, and may function as a drift region for the N-type LDMOS device. The N-type well region 12, the P-type well region 14 and the high-voltage N-type well region 13 may be a portion of the substrate 2, and may formed by various ion implantation processes. Bottom surfaces of the high-voltage N-type well region 13, the N-type well region 12 and the P-type well region 14 are at the same level. In some embodiments, the N-type well region 12 and the P-type well region 14 are shallow well regions.

Alternatively, the well regions 12, 13, and 14 may be portions of an epitaxy layer such as a silicon epitaxy layer formed by epitaxy processing. The N-type well region 12 and the high-voltage N-type well region 13 may have an N-type dopant such as phosphorus, and the P-type well region 14 may have a P-type dopant such as boron. In some embodiment, the well regions 12, 13, and 14 may be formed by a plurality of processing steps, whether now known or to be developed, such as growing a sacrificial oxide on substrate, opening a pattern for the location(s) of the P-type well regions or N-type well regions, and implanting the impurities.

In some embodiments, the N-type doping material of the N-type well region 12 and high-voltage N-type well region 13 includes, for example, but is not limited to, phosphorus, arsenic, nitrogen, antimony, or combinations thereof. Other suitable doping materials are within the contemplated scope of the present disclosure. The P-type doping material of the P-type well region 14 includes, for example, but is not limited to, boron, gallium, aluminum, indium, or combinations thereof. Other suitable doping materials are within the contemplated scope of the present disclosure. In some embodiments, the P-type well region 14 may be formed by diffusion.

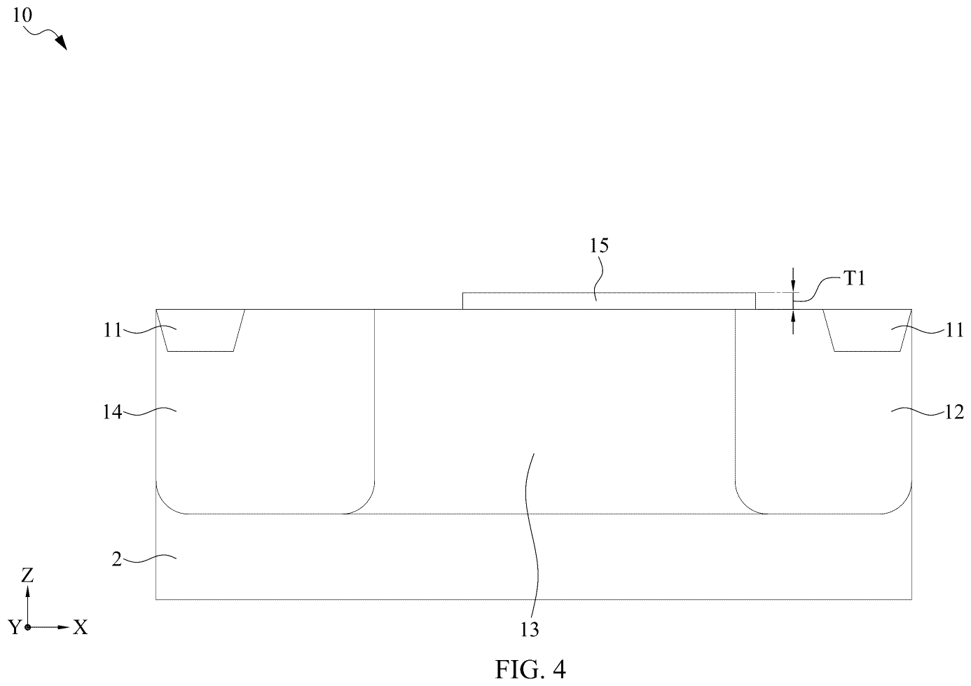

Corresponding to operation S106 of FIG. 1, FIG. 4 is a cross-sectional view of the semiconductor device 10 including a ROX layer 15, in which the well regions 12, 13, and 14 (FIG. 3) have been formed. The ROX layer 15 is formed and patterned on the N-type well region 12 and the high-voltage N-type well region 13. The ROX layer 15 can be, for example, but is not limited to, a silicon dioxide (SiO₂) layer with thickness T1 ranging from 350 Å to 500 Å. In some embodiments, the ROX layer 15 can be grown using thermal oxidation or in-situ steam generation (ISSG), and then patterned by a suitable process known to those skilled in the art of semiconductor fabrication.

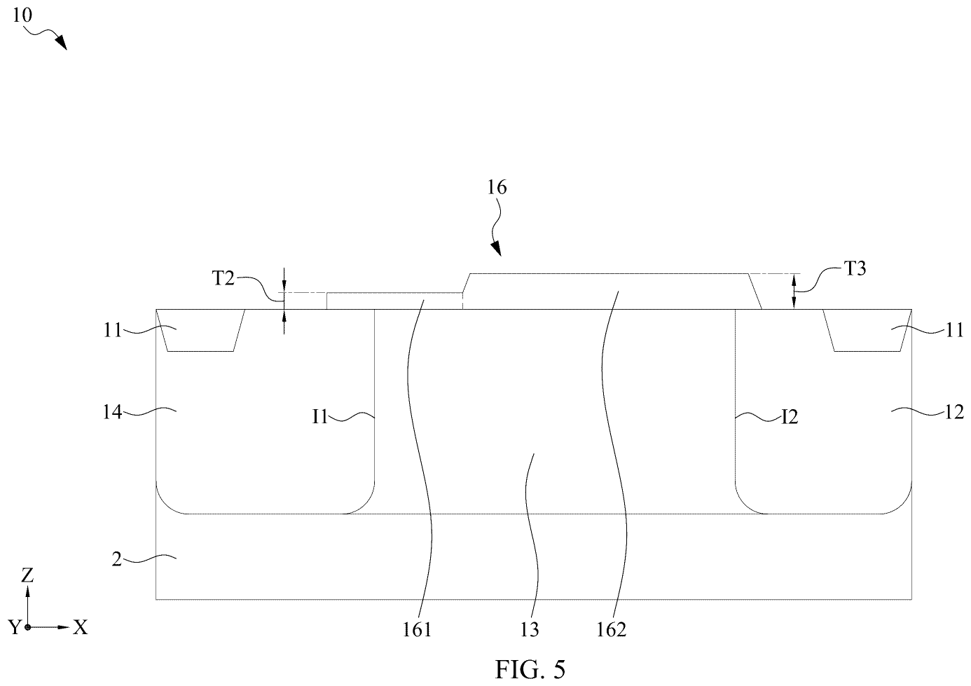

Corresponding to operation S108 of FIG. 1, FIG. 5 is a cross-sectional view of the semiconductor device 10 including a gate oxide layer 16. The gate oxide layer 16 includes an input/output (I/O) oxide layer portion 161 having a thickness T2 (e.g., 130 Å) and a ROX layer portion 162 having a thickness T3 ranging from 400 Å to 600 Å. The ROX layer portion 162 is formed over the N-type well region 12 and the high-voltage N-type well region 13, and the I/O oxide layer portion 161 is formed over the P-type well region 14 and the high-voltage N-type well region 13. The I/O oxide layer portion 161 overlaps an interface I1 between the P-type well region 14 and the high-voltage N-type well region 13, and the ROX layer portion 162 overlaps an interface 12 between the N-type well region 12 and the high-voltage N-type well region 13. A thickness ratio of the ROX layer portion 162 to the I/O oxide layer portion 161 is greater than 3. In some embodiments, the thickness T2 is less than the thickness T1. In some embodiments, a difference between the thickness T2 and the thickness T3 is determined by the thickness T1. Furthermore, the bottom surfaces of the I/O oxide layer portion 161 and the ROX layer portion 162 are at the same level. In some embodiments, a width of the I/O oxide layer portion 161 is less than a width of the ROX layer portion 162 in the X-axis.

In some embodiments, the gate oxide layer 16 is a fully oxidized gate oxide layer. The fully oxidized gate oxide layer may be formed by, for example but not limited to, rapid thermal oxidation (RTO). During the RTO process, the substrate 2 formed with the ROX layer 15 is rapidly heated in a chamber to a temperature ranging, and gaseous oxygen is charged into the chamber through a gas entry opening and exits the chamber through a gas exit opening, such that the thin dielectric silicon oxide layer is conformally formed to cover the ROX layer 15. The RTO process is further conducted in the chamber at the temperature range, with continuous charge and discharge of the gaseous oxygen into and from the chamber through the gas entry opening and the gas exit opening, respectively, so as to form the gate oxide layer 16 on the substrate 2.

In some embodiments, the gate oxide layer 16 is a pad oxide layer formed by thermally oxidizing a semiconductor substrate such as a silicon substrate, and a silicon nitride layer is deposited on the pad oxide. After the field oxide isolation structure is formed, the silicon nitride layer and the pad oxide layer are removed, respectively, usually by wet etching with hot phosphoric acid and an aqueous solution of hydrofluoric acid.

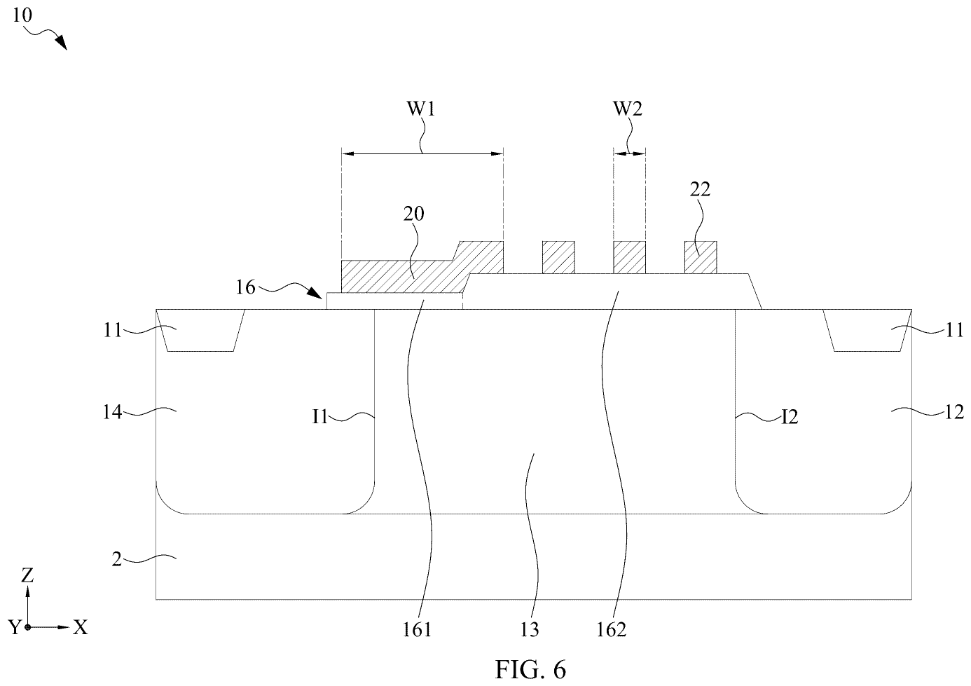

Corresponding to operation S110 of FIG. 1, FIG. 6 is a cross-sectional view of the semiconductor device 10 including a main gate 20 and a number of split gates 22, in which the gate oxide layer 16 has been formed. The main gate 20 is formed on the I/O oxide layer portion 161 and a portion of the ROX layer portion 162, and the split gates 22 are formed on the ROX layer portion 162. Furthermore, the main gate 20 is formed over the P-type well region 14 and the high-voltage N-type well region 13, and the split gates 22 are formed over the high-voltage N-type well region 13. The main gate 20 and the split gates 22 are formed by the same process and have the same thickness along the Z-axis. For example, a polysilicon layer is to have a suitable thickness on the gate oxide layer 16 by a suitable deposition process as is known to those skilled in the art of semiconductor fabrication, for example but not limited to, CVD, ALD, high density plasma CVD (HDP-CVD), remote plasma CVD (RPCVD), PECVD, or PEALD. Other suitable deposition processes are within the contemplated scope of the present disclosure. In some embodiments, the polysilicon layer may be formed by CVD using silane (SiH₄) as a chemical gas. A hard mask layer (not shown) is patterned using photolithography and photoresist developing technology as known to those skilled in the art of semiconductor fabrication. For example, the hard mask layer may be patterned using immersion lithography or extreme ultraviolet (EUV) lithography. The pattern formed in the hard mask layer is then transferred to the polysilicon layer by etching (for example but not limited to, dry etching) so as to form the main gate 20 and the split gates 22.

The main gate 20 is disposed over an interface I1 between the high-voltage N-type well region 13 and the P-type well region 14, and extends along the interface I1 between the high-voltage N-type well region 13 and the P-type well region 14, e.g., extending along the Y-axis. In other words, the main gate 20 overlaps the interface I1 between the high-voltage N-type well region 13 and the P-type well region 14. The split gates 22 are disposed over the high-voltage N-type well region 13. Along the X-axis, a width W1 of the main gate 20 is greater than a width W2 of the split gates 22. In some embodiments, a width of the main gate 20 overlapping the ROX layer portion 162 is equal to or less than the width W2 in the X-axis. Furthermore, an area of the main gate 20 overlapping the ROX layer portion 162 is less than an area of the split gates 22 overlapping the ROX layer portion 162 from a top view. Moreover, a width of the main gate 20 overlapping the ROX layer portion 162 is less than a width of the main gate 20 overlapping the I/O oxide layer portion 161. In the semiconductor device 10, the split gates 22 and the main gate 20 are the same length in the Y-axis. Furthermore, the number of split gates 22 is an example and is not intended to limit the disclosure. In some embodiments, the semiconductor device 10 may include more or fewer split gates 22 on the ROX layer portion 162. Furthermore, the split gates 22 serve as the poly field plate (PFP) for controlling fluctuation of BVdss and effective field distribution.

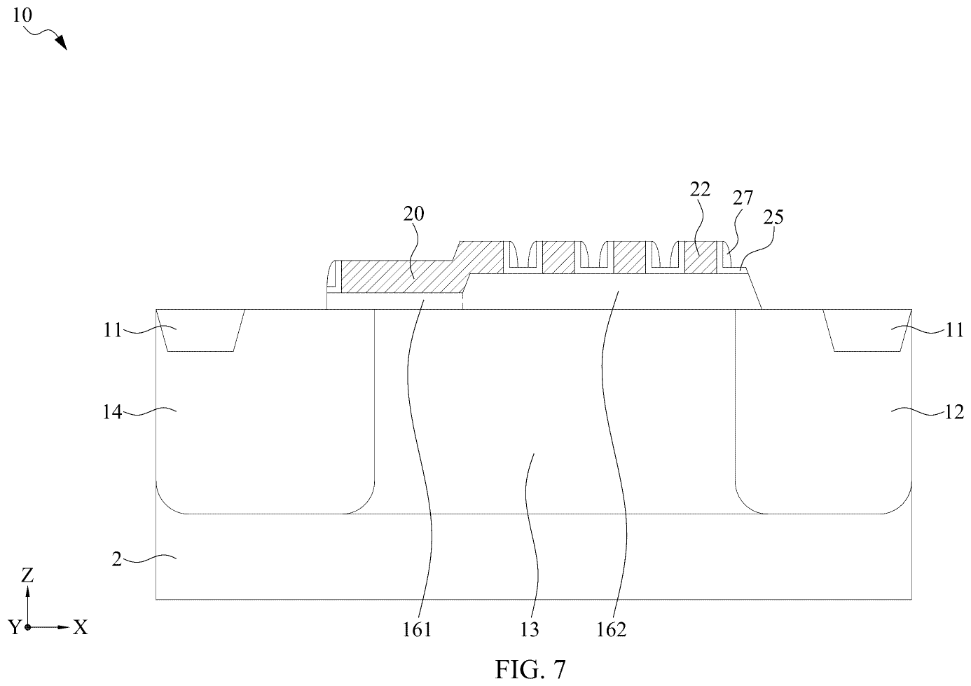

Corresponding to operations S112 and S114 of FIG. 1, FIG. 7 is a cross-sectional view of the semiconductor device 10 including a dielectric buffer layer 25 and a number of spacers 27, in which the main gate 20 and the split gates 22 have been formed. The dielectric buffer layer 25 is formed on the gate oxide layer 16 and the sidewalls of the main gate 20 and the split gates 22. The dielectric buffer layer 25, for example but not limited to, may be a dielectric silicon oxide layer. In some embodiments, the dielectric buffer layer 25 is conformally deposited to cover the main gate 20, the split gates 22, the gate oxide layer 16 and the substrate 2 and then the dielectric buffer layer 25 overlapping the substrate 2, the main gate 20 and the split gates 22 is removed. The deposition and removal of the dielectric buffer layer 25 may be performed using suitable processes as are known to those skilled in the art of semiconductor fabrication.

The spacers 27 extend upwardly from horizontal portions of the dielectric buffer layer 25 and laterally cover vertical portions of the dielectric buffer layer 25. The processes of the spacers 27 may be performed using suitable processes as are known to those skilled in the art of semiconductor fabrication. The spacers 27 are formed by a spacer layer. The spacer layer may be of at least one dielectric material, for example but not limited to, silicon oxide, silicon nitride, silicon carbide, silicon oxycarbide, silicon oxynitride, silicon carbonitride, silicon oxycarbonitride, or combinations thereof. Other suitable dielectric materials are within the contemplated scope of the present disclosure.

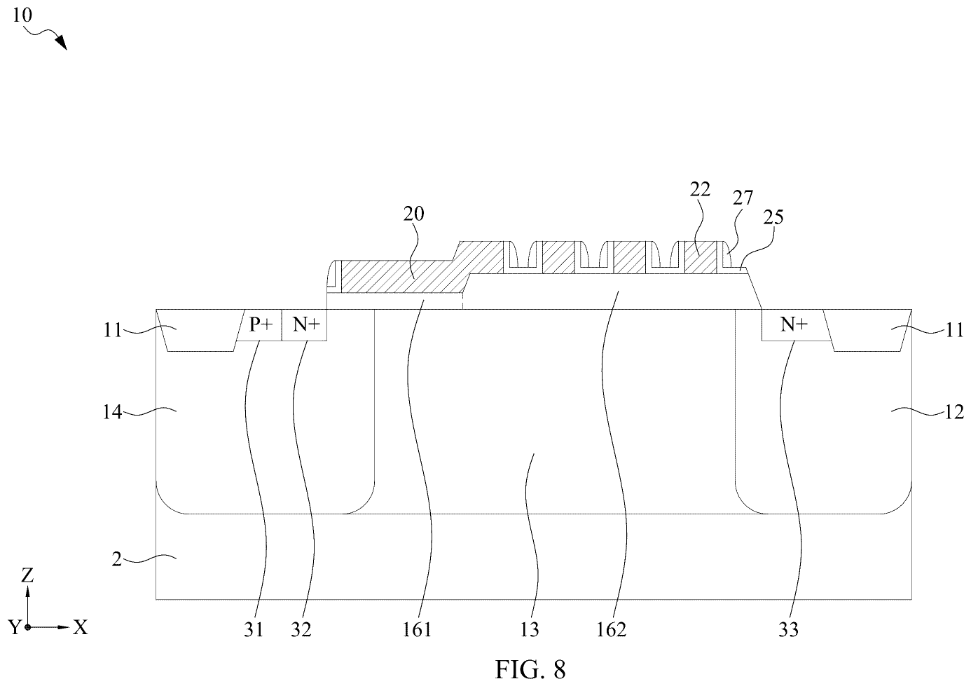

Corresponding to operation S116 of FIG. 1, FIG. 8 is a cross-sectional view of the semiconductor device 10 including a bulk region 31, a source region 32 and a drain region 33. The bulk region 31 and the source region 32 are formed in the P-type well region 14, and the drain region 33 is formed in the N-type well region 12. The source region 32 is disposed adjacent to the main gate 20. The drain region 33 is disposed adjacent to the split gates 22. The source region 32 and drain region 33 are formed simultaneously by doping the P-type well region 14 and the N-type well region 12 with an N-type dopant, for example but not limited to, phosphorous or arsenic, through a patterned photoresist layer (not shown) removed after the source region 32 and the drain region 33 are formed. Furthermore, the bulk region 31 is formed by doping the P-type well region 14 with a P-type dopant.

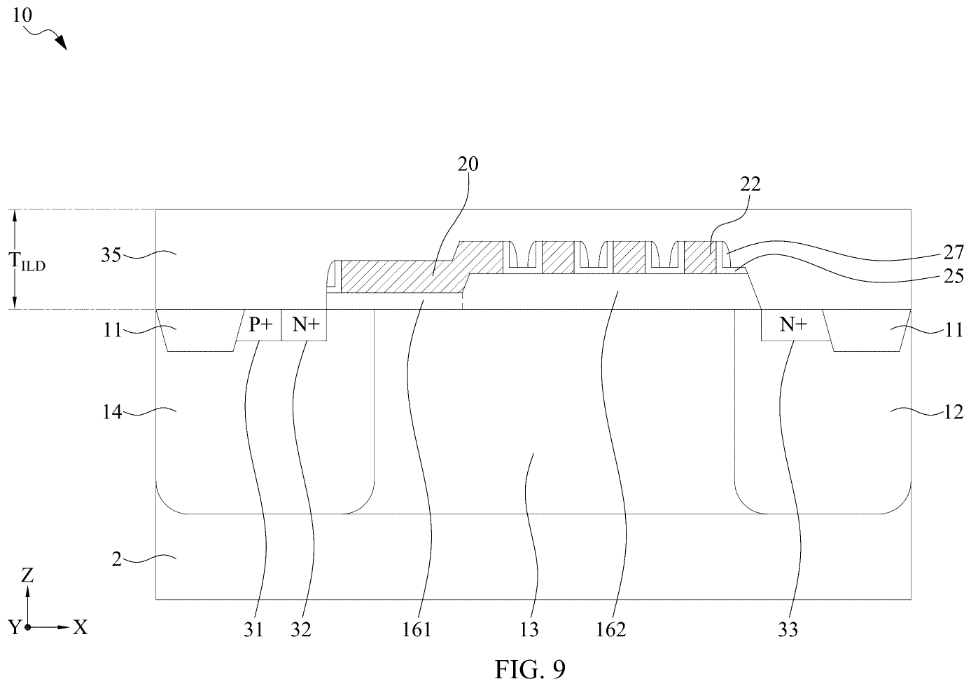

Corresponding to operation S118 of FIG. 1, FIG. 9 is a cross-sectional view of the semiconductor device 10 including an interlayer dielectric (ILD) layer 35. The ILD layer 35 is formed with a thickness TILD sufficient to embed or otherwise overlay features currently formed over the substrate 2. For example, features of the semiconductor device 10 at the current fabrication stage may be further overlaid by the ILD layer 35. In order to simplify the description, some features of the semiconductor device 10 will be omitted, such as a contact etch stop layer, a resist protect oxide (RPO) layer, salicide regions and so on.

In some embodiments, the ILD layer 35 is formed of a dielectric material such as silicon oxide, phosphosilicate glass (PSG), borosilicate glass (BSG), boron-doped phosphosilicate Glass (BPSG), undoped silicate glass (USG), or the like, and may be deposited by any suitable method such as CVD, PECVD, or FCVD. After the ILD is formed, an optional dielectric protection layer (not shown) is formed over the ILD. The dielectric protection layer can prevent or reduce the loss of the ILD in subsequent etching processes. The dielectric protection layer may be formed of a suitable material such as silicon nitride, silicon carbonitride, or the like, using a suitable method such as CVD, PECVD, or FCVD.

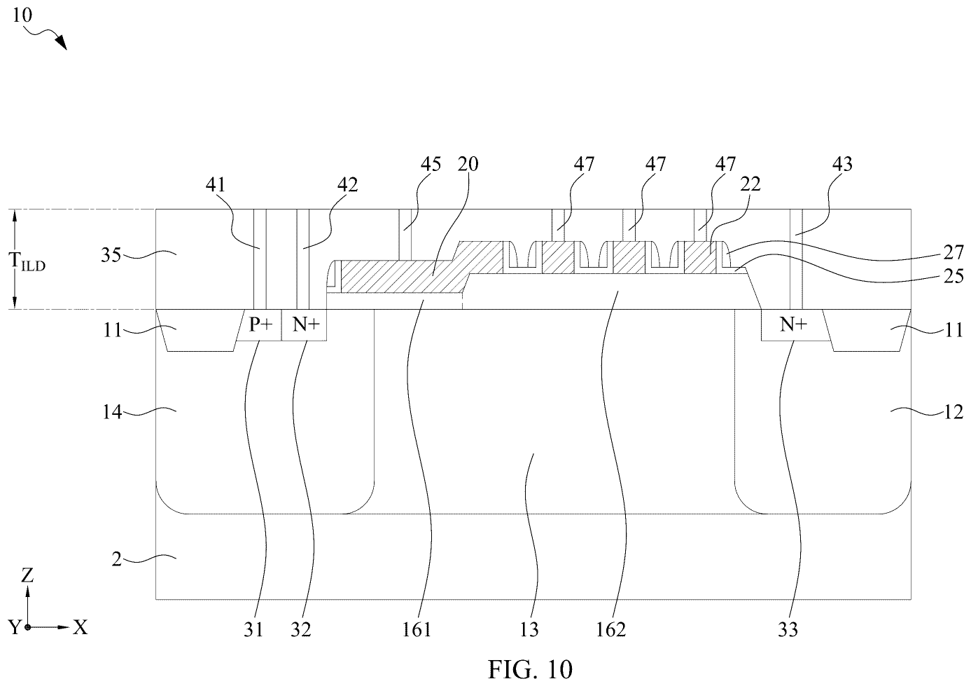

Corresponding to operation S120 of FIG. 1, FIG. 10 is a cross-sectional view of the semiconductor device 10 including a number of contact plugs 41, 42, 43, 45 and 47. The contact plugs 41, 42, 43, 45 and 47 are the connecting features extending through the ILD layer 35 to electrically couple to the corresponding features. For example, the contact plug 41 penetrates the ILD layer 35 to contact the bulk region 31, the contact plug 42 penetrates the ILD layer 35 to contact the source region 32, and the contact plug 43 penetrates the ILD layer 35 to contact the drain region 33. Along the Z-axis, the contact plugs 41, 42, and 43 have the same thickness (or height), e.g., the thickness TILD. The contact plug 45 penetrates the ILD layer 35 to contact the main gate 20, and the contact plugs 47 penetrate the ILD layer 35 to contact the split gates 22. The contact plug 45 is thicker than the contact plugs 47, and the contact plugs 41, 42, and 43 are thicker than the contact plug 45. In some embodiments, the contact plugs 41, 42, 43, 45 and 47 are formed by one or more conductive materials. In some embodiments, the one or more conductive materials may include tungsten (W), titanium (Ti), titanium nitride (TiN), and/or tantalum nitride (TaN).

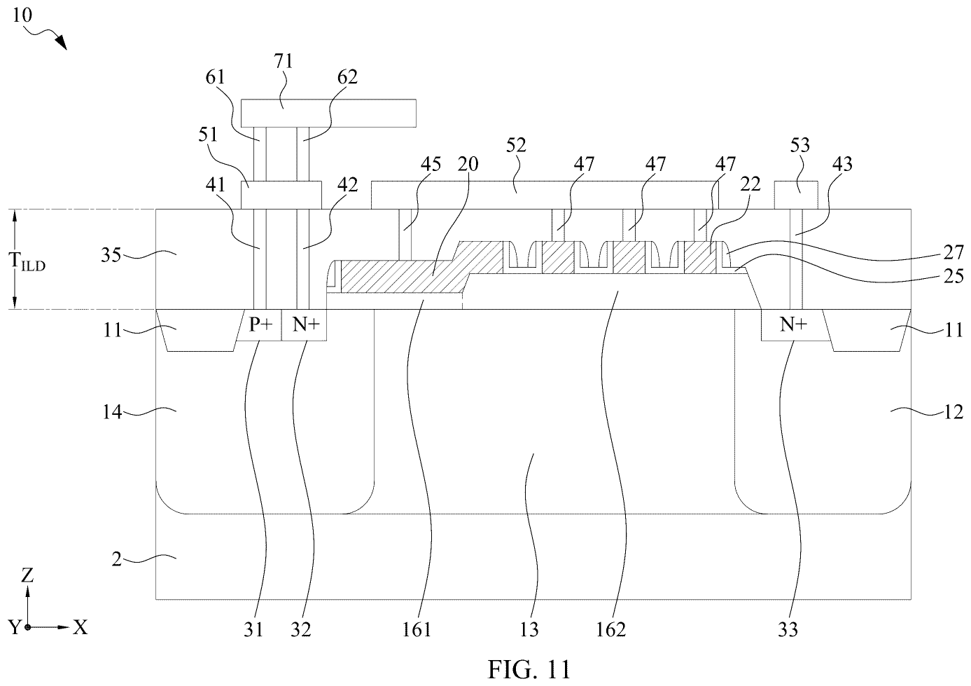

Corresponding to operation S122 of FIG. 1, FIG. 11 is a cross-sectional view of the semiconductor device 10 including a number of interconnection structures. The interconnection structures are formed in an inter-metal dielectric (IMD) layer (not shown) over the ILD layer 35. The metal lines (or electrodes) 51, 52, and 53 of the interconnection structures are formed in the lowest metal layer. The metal lines 51, 52, and 53 can be electrically connected to the upper metal lines through the vias. For example, the metal line 51 is electrically connected to the metal line 71 through the vias 61 and 62.

In the embodiment of FIG. 11, the metal line 51 of a first interconnection structure is formed to contact the contact plugs 41 and 42 so that the source region 32 is electrically connected to the bulk region 31 and other device or circuit (not shown) through the first interconnection structure. The metal line 53 of a second interconnection structure is formed to contact the contact plug 43 so that the drain region 33 is electrically connected to other device or circuit (not shown) through the second interconnection structure. The metal line 52 of a third interconnection structure is formed to contact the contact plugs 45 and 47 so that the main gate 20 is electrically connected to the split gates 22 and other device or circuit (not shown) through the third interconnection structure.

Compared with conventional BCD, the drift region of the semiconductor device 10 is controlled by the poly field plate formed by the split gates 22 overlapping the ROX layer portion 162, thereby avoiding uncontrollable BVdss. In other words, the thickness TILD will not affect the control of the drift region. Furthermore, by simultaneously controlling the main gate 20 and the split gates 22, the channel region and the drift region of the semiconductor device 10 can be turned off at the same time, thereby avoiding leakage caused by the failure of the poly field plate to immediately turn off the drift region in conventional BCD. The ROX layer portion 162 has the thicker thickness, thus the split gates 22 and the main gate 20 on the ROX layer portion 162 can both relieve HCl injection without considering the drift region implant, thereby decreasing fluctuation in HCl and BVdss. Moreover, a portion of the main gate 20 is formed on the ROX layer portion 162 to avoid forming features (e.g., the spacers, the RPO layer, etc.) at an interface between the I/O oxide layer portion 161 and the ROX layer portion 162 because features formed at interfaces with height differences can easily cause process issues. Furthermore, thickness adjustment of the ROX layer portion 162 is flexible in process, and is compatible with the logic processes in the BCD.

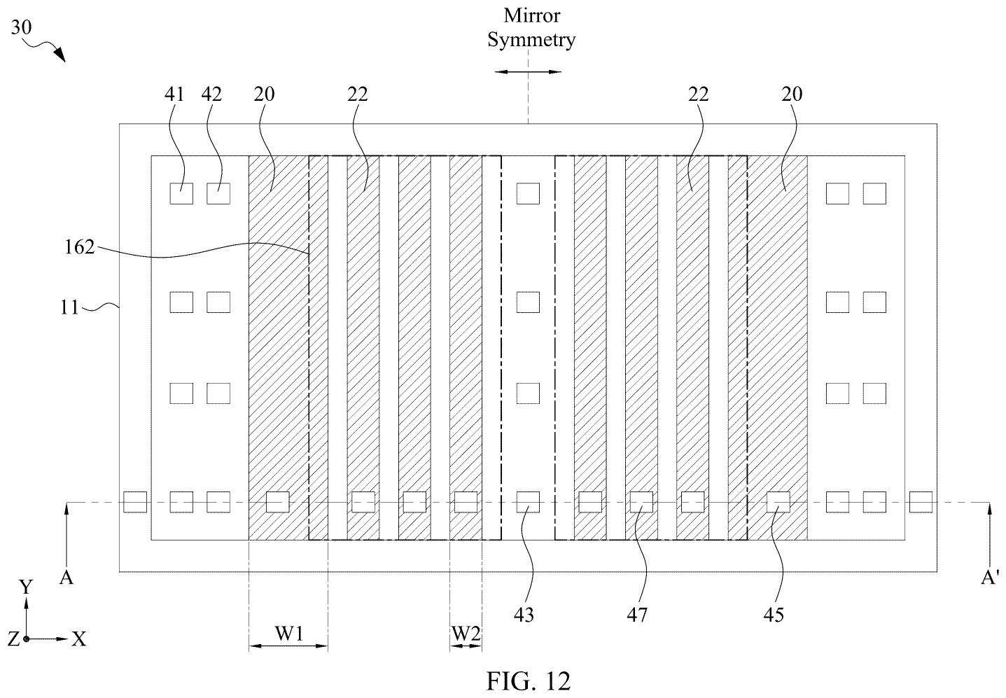

FIG. 12 is a top view of a semiconductor device 30, in accordance with some embodiments of the disclosure. The semiconductor device 30 is a common drain structure symmetrical along a Y-axis. In the semiconductor device 30, the main gate 20 has a width W1 along the X-axis and the split gates 22 each has a width W2 along the X-axis, and the width W1 is greater than the width W2. Furthermore, the split gates 22 and the main gate 20 have the same length along the Y-axis.

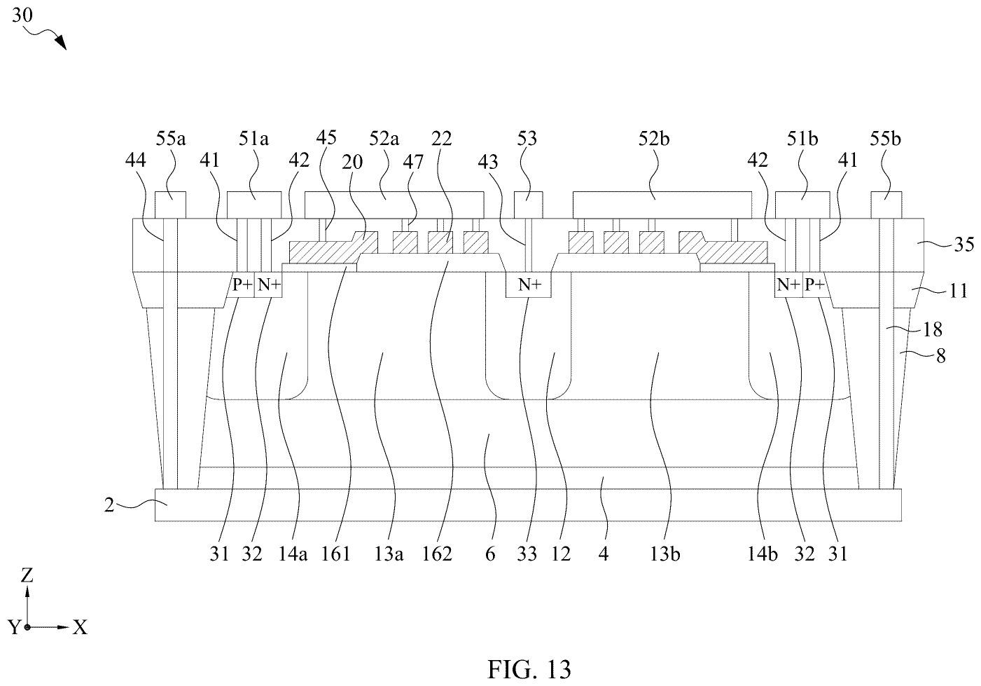

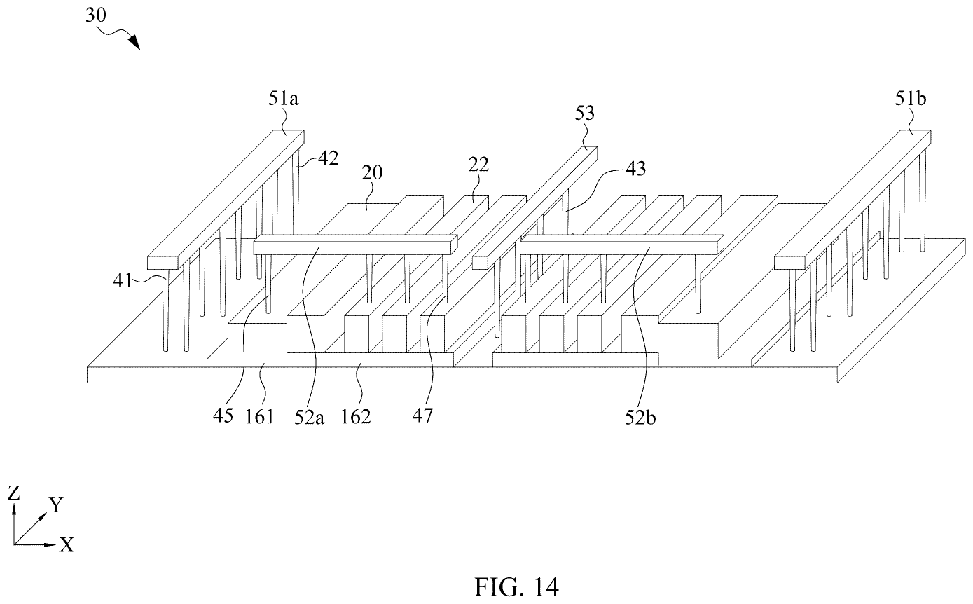

FIG. 13 is a cross-section of the semiconductor device 30 of FIG. 12 along line A-A′, and FIG. 14 is a perspective view of interconnection structures of the semiconductor device 30 of FIG. 12, in accordance with some embodiments of the present disclosure. In order to simplify the description, some features of the semiconductor device 30 will be omitted in FIG. 14.

Referring to FIGS. 12 to 14, the semiconductor device 30 is formed in a SOI structure. Compared with the semiconductor device 10 shown in FIG. 11, the semiconductor device 30 further includes a BOX layer 4, a P-type epitaxy layer 6 and the isolation structures 8. The BOX layer 4 is formed underneath the P-type epitaxial layer 6, and the P-type epitaxial layer 6 is formed underneath the high-voltage well regions 13a and 13b, the P-type well regions 14a and 14b and the N-type well region 12. The high-voltage well regions 13a and 13b are separated by the N-type well region 12. The isolation structure 8 is formed underneath the isolation structure 11. The connection features 18 penetrate the isolation structures 11 and 8 to contact the substrate 2 underneath the BOX layer 4. In some embodiments, the connection features 18 are through-silicon vias (TSVs).

In the semiconductor device 30, the contact plugs 41 and 42 are configured to connect the bulk regions 31 and the source regions 32 in the P-type well regions 14a and 14b to a first interconnection structure including the metal lines 51a and 51b. The contact plugs 43 are configured to connect the drain region 33 to a second interconnection structure including the metal line 53. The contact plugs 45 and 47 are configured to connect the main gate 20 and the split gates 22 to a third interconnection structure including the metal lines 52a and 52b. The contact plugs 44 are configured to connect the connection features 18 to a reference voltage (or node) through a fourth interconnection structure including the metal lines 55a and 55b. In some embodiments, the fourth interconnection structure is electrically connected to the first interconnection structure, e.g., the connection features 18 is electrically connected to the bulk region 31 and the source region 32. In some embodiments, the first to fourth interconnection structures are formed in the IMD layer in BEOL process.

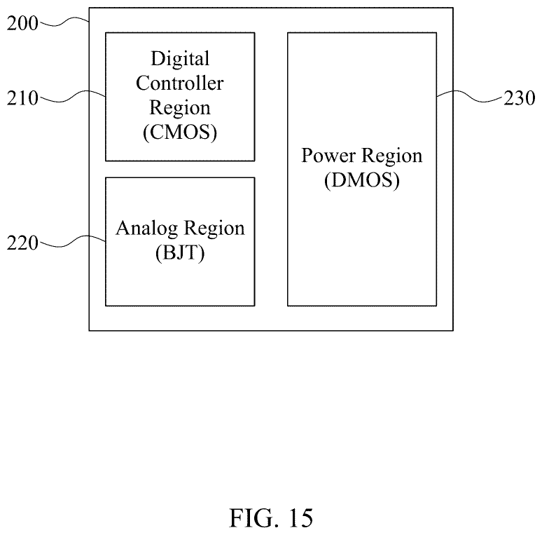

FIG. 15 is an integrated semiconductor device 300, in accordance with some embodiments of the disclosure. The integrated semiconductor device 300 is a BCD device, and includes a digital controller region 210 with CMOS transistors, an analog region 220 with BJTs, and a power region 230 with DMOS transistors (e.g., the semiconductor devices 10 and 30). In various embodiments, the DMOS transistors of the power region 230 may include high voltage applications that may benefit from the additional application of CFPs with split gates as discussed in any of the embodiments above.

In some embodiments, the power region 230 is arranged in a high voltage area, and the digital controller region 210 and the analog region 220 are arranged in a low voltage area. In some embodiments, the devices in the high voltage area operate at voltages greater than 10V, such as greater than 50V, such as greater than 100V, such as greater than 200V. The devices in the low voltage area operate at voltages less than 10V, such as less than 5V, such as less than 3V.

According to some embodiments, a method for manufacturing a semiconductor device is provided. The method includes the following operations. A gate oxide layer is formed over a high-voltage N-type well region, an N-type well region and a P-type well region, and the gate oxide layer includes a first layer portion and a second layer portion, and the first and second layer portions have different thicknesses. A main gate is formed on the first layer portion and the second layer portion. At least one split gate is formed on the second layer portion, and the main gate and the split gate extend along an interface between the high-voltage N-type well region and the P-type well region. An inter-level dielectric (ILD) layer is formed over the main gate and the split gate. A plurality of connecting features penetrating the ILD layer to contact the main gate and the split gate are formed. An electrode is formed to contact the connecting features.

According to some embodiments, a method for manufacturing a semiconductor device is provided. The method includes the following operations. An N-type well region is formed in a substrate. A P-type well region is formed in the substrate. A high-voltage well region is formed in the substrate and between the N-type well region and the P-type well region. A gate oxide layer is formed over the substrate, and the gate oxide layer includes a reduced surface field oxide (ROX) layer portion on the N-type well region and the high-voltage well region, and an input/output (I/O) oxide layer portion on the high-voltage well region and the P-type well region. A main gate and a plurality of split gates are formed on the gate oxide layer. The main gate overlaps the ROX layer portion and the I/O oxide layer portion, and the split gates overlap the ROX layer portion. An interconnection structure is formed over the main gate and the split gates, and the main gate is electrically connected to the split gates through the interconnection structure.

According to some embodiments, a semiconductor device is provided. The semiconductor device includes a gate oxide layer over a substrate, a main gate, a plurality of split gates, an inter-level dielectric (ILD) layer over the main gate and the split gate, a plurality of connecting features and a metal line. The gate oxide layer includes an input/output (I/O) oxide layer portion on a high-voltage N-type well region and a P-type well region of the substrate, and a reduced surface field oxide (ROX) layer portion on the high-voltage N-type well region and an N-type well region of the substrate. The ROX layer portion is thicker than the I/O oxide layer portion. The main gate is disposed on the I/O oxide layer portion and the ROX layer portion. The split gates are disposed on the ROX layer portion. The connecting features penetrate the ILD layer to contact the main gate and the split gates. The metal line is formed over the ILD layer and contacts the connecting features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a gate oxide layer over a high-voltage N-type well region, an N-type well region and a P-type well region, wherein the gate oxide layer comprises a first layer portion and a second layer portion, and the first and second layer portions have different thicknesses;
forming a main gate on the first layer portion and the second layer portion;
forming at least one split gate on the second layer portion, wherein the main gate and the split gate extend along an interface between the high-voltage N-type well region and the P-type well region;
forming an inter-level dielectric (ILD) layer over the main gate and the split gate;
forming a plurality of connecting features penetrating the ILD layer to contact the main gate and the split gate; and
forming an electrode to contact the connecting features.

2. The method of claim 1, wherein a thickness ratio of the second layer portion to the first layer portion is greater than 3.

3. The method of claim 1, further comprising:
forming a source region in the P-type well region; and
forming a drain region in the N-type well region.

4. The method of claim 1, wherein the first layer portion overlaps the interface between the high-voltage N-type well region and the P-type well region, and the second layer portion overlaps an interface between the high-voltage N-type well region and the N-type well region.

5. The method of claim 1, wherein the first layer portion overlaps the interface between the high-voltage N-type well region and the P-type well region.

6. The method of claim 1, wherein the main gate and the split gate have the same thickness.

7. The method of claim 1, wherein a width of the main gate is greater than a width of the split gate in a direction perpendicular to the interface between the high-voltage N-type well region and the P-type well region.

8. The method of claim 1, further comprising:
forming the high-voltage N-type well region, the N-type well region and the P-type well region in a substrate,
wherein bottom surfaces of the high-voltage N-type well region, the N-type well region and the P-type well region are at the same level.

9. The method of claim 1, wherein forming the connecting features penetrating the ILD layer to contact the main gate and the split gate further comprises:
forming a first connecting feature to contact the main gate overlapping the first layer portion; and
forming a second connecting feature to contact the split gate,
wherein the first connecting feature is thicker than the second connecting feature.

10. The method of claim 1, wherein the first layer portion is an input/output (I/O) oxide layer portion and the second layer portion is a reduced surface field oxide (ROX) layer portion, and a width of the second layer portion is greater than a width of the first layer portion in a direction perpendicular to the interface between the high-voltage N-type well region and the P-type well region.

11. The method of claim 1, wherein a width of the main gate overlapping the first layer portion is greater than a width of the main gate overlapping the second layer portion in a direction perpendicular to the interface between the high-voltage N-type well region and the P-type well region.

12. A method for manufacturing a semiconductor device, comprising:
forming an N-type well region in a substrate;
forming a P-type well region in the substrate;
forming a high-voltage well region in the substrate and between the N-type well region and the P-type well region;
forming a gate oxide layer over the substrate, wherein the gate oxide layer comprises a reduced surface field oxide (ROX) layer portion on the N-type well region and the high-voltage well region, and an input/output (I/O) oxide layer portion on the high-voltage well region and the P-type well region;
forming a main gate and a plurality of split gates on the gate oxide layer, wherein the main gate overlaps the ROX layer portion and the I/O oxide layer portion, and the split gates overlap the ROX layer portion; and
forming an interconnection structure over the main gate and the split gates, wherein the main gate is electrically connected to the split gates through the interconnection structure.

13. The method of claim 12, wherein a thickness ratio of the ROX layer portion to the I/O oxide layer portion is greater than 3, and the main gate and the split gates have the same thickness.

14. The method of claim 12, further comprising:
forming a epitaxial layer underneath the high-voltage well region, the P-type well region and the N-type well region;
forming a buried oxide layer underneath the epitaxial layer;
forming an isolation region penetrating the P-type well region, the epitaxial layer and the buried oxide layer; and
forming a connecting feature penetrating the isolation region to contact the substrate underneath the buried oxide layer.

15. A semiconductor device, comprising:
a gate oxide layer over a substrate, comprising:
an input/output (I/O) oxide layer portion on a high-voltage N-type well region and a P-type well region of the substrate; and
a reduced surface field oxide (ROX) layer portion on the high-voltage N-type well region and an N-type well region of the substrate, wherein the ROX layer portion is thicker than the I/O oxide layer portion;
a main gate disposed on the I/O oxide layer portion and the ROX layer portion;
a plurality of split gates disposed on the ROX layer portion;
an inter-level dielectric (ILD) layer over the main gate and the split gate;
a plurality of connecting features penetrating the ILD layer to contact the main gate and the split gates; and
a metal line over the ILD layer and contacting the connecting features.

16. The semiconductor device of claim 15, further comprising:
a source region formed in the P-type well region; and
a drain region formed in the N-type well region.

17. The semiconductor device of claim 15, wherein a thickness ratio of the ROX layer portion to the I/O oxide layer portion is greater than 3.

18. The semiconductor device of claim 15, wherein the main gate and the split gates have the same thickness.

19. The semiconductor device of claim 15, wherein the main gate and the split gates extend along an interface between the high-voltage N-type well region and the P-type well region.

20. The semiconductor device of claim 15, wherein a width of the main gate is greater than a width of the split gates in a direction perpendicular to an interface between the high-voltage N-type well region and the P-type well region.
